(19) United States
(12) Patent Application Publication
(10) Pub. No.: US 2004/0178941 A1
(43) Pub. Date: Sep. 16, 2004

(54) Data stream processing system of direct stream digital technology

(75) Inventors: Wei-Hung Huang, Hsin-Chu City (TW); Yung-Teng Lin, Hsin-Chu City (TW)

Correspondence Address: TROXELL LAW OFFICE PLLC, SUITE 1404, 5205 LEESBURG PIKE, FALLS CHURCH, VA, 22041, US

(73) Assignee: MediaTek Inc.

(21) Appl. No.: 10/796,184

(22) Filed: Mar. 10, 2004

(30) Foreign Application Priority Data
Mar. 11, 2003 (CN) 092105264

(51) Int. Cl. H03M 1/66

(52) U.S. Cl. 341/144

(57) ABSTRACT

The invention provides a data stream processing system applied for Direct Stream Digital technology (DSD). The system converts each original digital data streams processed by DSD into corresponding analog signals. The system comprises a combining module, a clock generating module, and a digital-to-analog converter (DAC). Based on a combining rule, the combining module generates data streams by combining two original digital data streams into one data stream. The clock-generating module generates a first clock signal to define a predetermined converting period for the data streams and a second clock signal to trigger a converting process for each digital data of the data streams. The DAC converts each digital data of each data streams into a plurality of corresponding analog signals, based on the first and the second clock signals.

### BACKGROUND OF THE INVENTION

1. Field of the Invention

This present invention relates to a data processing system, particularly to a data processing system of Direct Stream Digital (DSD) technology and the processing method thereof.

2. Description of the Prior Art

FIG. 1 illustrates a schematic diagram of a conventional Direct Stream Digital (DSD) data stream processing system 10. The conventional DSD data stream processing system 10 decodes the encoded digital signal 12 of four-channel audio data to four corresponding analog audio sound waves 14a, 14b, 14c, and 14d. The data stream processing system 10 includes a decoder 16, a digital-to-analog converter (DAC) 18, and four speakers 20a, 20b, 20c, and 20d.

The decoder 16 is used for decoding the encoded digital signal 12, which is carried on at least one signal line, back to its four original digital data streams 20a, 22b, 22c, and 22d. The decoder 16 has a clock generating module 11 for generating a second clock signal 24 and a third clock signal 26, and the decoder 16 outputs these four original digital data streams 22a, 22b, 22c, 22d, the second clock signal 24, and the third clock signal 26 to the DAC 18.

According to the four inputted original digital data streams 22a, 22b, 22c, 22d, the second clock signal 24 and the third clock signal 26, the DAC 18 converts the original digital data streams 22a, 22b, 22c, 22d into corresponding analog signals 28a, 28b, 28c, 28d, and outputs these analog signals 28a, 28b, 28c, 28d to the corresponding speakers 20a, 20b, 20c, 20d.

Then the four speakers 20a, 20b; 20c, 20d output corresponding analog audio sound waves 14a, 14b, 14c, 14d according to the input analog signals 28a, 28b, 28c, 28d.

The second clock signal 24 is used for triggering a converting function of each digital data of the original data streams 22a, 22b, 22c, and 22d. The third clock signal 26 is an oversampling reference clock in the DSD technology.

FIG. 2 illustrates a signal diagram of the original digital data streams 22a, 22b, 22c, 22d and the second clock signal 24 in FIG. 1. In the signal diagram, the horizontal axis denotes time line, and the vertical axis denotes the amplitude of the signals. The second clock signal 24 in FIG. 2 includes a plurality of square waves 30, and each square wave 30 has a positive edge 32. At the moment when each positive edge 32 of the square wave 30 appears, there is one corresponding digital data, for example represented as aD0, bD0, cD0, or dD0, in each of the original digital data streams 22a, 22b, 22c, or 22d respectively. In FIG. 2, mDn is used to show these corresponding digital data, which may include one or more digital data bits; wherein m denotes one of the four corresponding original digital data streams 22a, 22b, 22c, and 22d, and n denotes a sequential number. The sequential number is a series of natural numbers increasing with time. For example, aD0 indicates the 0th digital data bit of the original digital data stream 22a, and cDn−1 indicates the (n−1)th digital data of the original digital data stream 22c.

In FIG. 1 and FIG. 2, when the positive edge 32 of the square wave 30 appears in the second clock signal 24, the DAC 18 converts the corresponding digital data mDn in the original digital data streams 22a, 22b, 22c, and 22d into four analog signals 28a, 28b, 28c, and 28d respectively.

Therefore, the conventional DSD data stream processing system 10 needs at least six signal lines to process four-channel audio data, so as to connect the decoder 16 with the DAC 18. The six signal lines are for the four original digital data streams 22a, 22b, 22c, 22d, the second clock signal 24, and the third clock signal 26. Therefore, if the number of channels increases, the number of required signal lines must also increase. That is, increasing one additional channel requires increasing one additional signal line. For example, 2-channel audio data needs at least 4 signal lines, 4-channel audio data needs at least 6 signal lines, and 6-channel audio data needs at least 8 signal lines.

As consumers request more channels of audio data, lighter and smaller product size, and lower product price, it is desired to reduce the number of signal lines so as to lower the cost and further reduce the product size.

### SUMMARY OF THE INVENTION

Accordingly, an objective of the present invention is to provide a data stream processing system of Direct Stream Digital (DSD) technology which decreases the number of data streams that are transmitted to the DAC, therefore decreases the signal lines, and further reduces the cost and the product size.

According to the present invention, a data processing system of DSD technology requires fewer number of data streams that are transmitted to a DAC. The system includes a combining module and a clock-generating module. The combining module combines two original digital data streams into one combined data stream based on a combining rule, and then a plurality of combined data streams are generated accordingly. The clock-generating module generates a first clock signal and a second clock signal. The first clock signal is used for defining a predetermined converting period of each data stream, and the second clock signal is used for triggering the DAC, converting each digital data of each data stream into a corresponding analog signal. In this way, then a plurality of corresponding analog signals are generated.

The data stream processing system of the present invention requires fewer number of data streams transmitted to the DAC, so the data stream processing system requires fewer number of signal lines and fewer number of pins. Therefore the cost and product size can be reduced.

The advantage and spirit of the invention may be understood by the following explanation together with the appended diagrams.

### BRIEF DESCRIPTION OF THE APPENDED DRAWINGS

FIG. 1 is a schematic diagram of a conventional DSD data stream processing system.

FIG. 2 is a signal diagram of the original data streams and the second clock signal in FIG. 1.

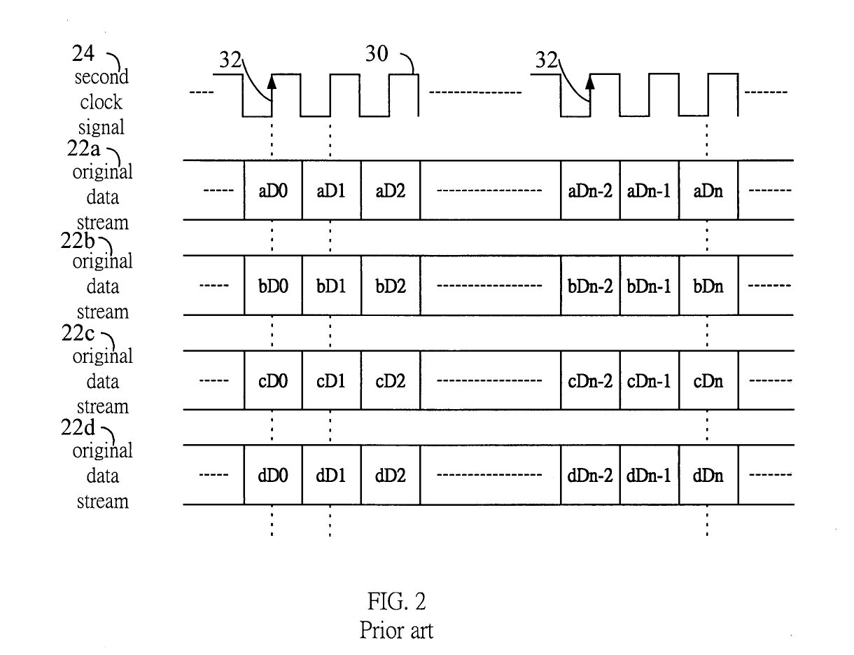

FIG. 3 is a schematic diagram of the data stream processing system according to the present invention.

FIG. 4 is a signal diagram of the data streams, the first clock signal, and the second clock signal in FIG. 3.

FIG. 5 is a schematic diagram of the data stream processing system in another embodiment according to the present invention.

FIG. 6 is a schematic diagram of a data stream processing system in another embodiment according to the present invention.

FIG. 7 is a schematic diagram of a data stream processing system in another embodiment according to the present invention.

FIG. 8 is a schematic diagram of a data stream transmission interface according to the present invention.

FIG. 9 is a flow chart of a data stream processing method according to the present invention.

### DETAILED DESCRIPTION OF THE INVENTION

The present invention provides a Direct Stream Digital (DSD) data processing system for converting the original digital data streams processed by DSD technology into corresponding analog signals, so as to reduce the number of digital data streams that need to be transmitted to the DAC.

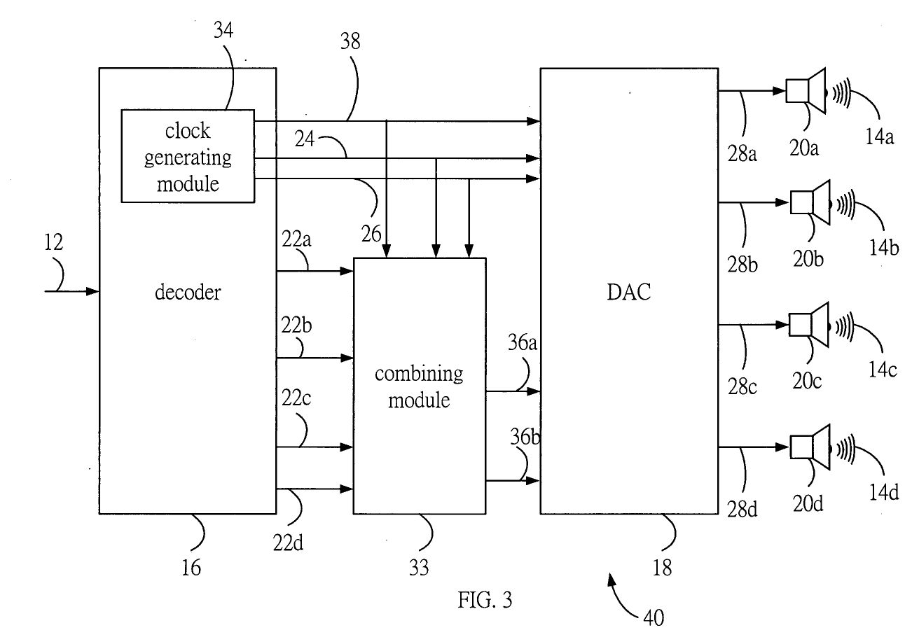

FIG. 3 illustrates a schematic diagram of the data stream processing system 40 according to the present invention. The data stream processing system 40 converts the four original digital data streams 22a, 22b, 22c, 22d processed by DSD technology into four corresponding analog signals 28a, 28b, 28c, 28d for output. The data stream processing system 40 includes a combining module 33, a clock generating module 34, and a digital-to-analog converter (DAC) 18. In this embodiment, the clock generating module 34 is incorporated inside the decoder 16.

The combining module 33 is used to combine every two original digital data streams into one combined data stream based on a combining rule so as to generate a plurality of combined digital data streams. In this embodiment, the combining module 33 combines every two of the four original digital data streams 22a, 22b, 22c, 22d and generates two combined digital data streams 36a, 36b according to the combining rule.

The clock-generating module 34 generates a first clock signal 38, a second clock signal 24, and a third clock signal 26. The first clock signal 38 is used for defining a predetermined converting period of each data stream 36a and 36b. The second clock signal 24 is used for triggering a converting function to convert each digital data, or the digital data bits therein, of the data streams 36a and 36b. The third clock signal 26 is the oversampling reference clock in DSD technology.

The DAC 18 converts each digital data of the data streams 36a, 36b into a corresponding analog signal 28a, 28b, 28c, and 28d based on the first clock signal 38 and the second clock signal 24.

The combining rule of the combining module 33 is to choose two original digital data streams from a plurality of original digital data streams 22a, 22b, 22c, and 22d. For example, the module may choose the original digital data streams 22a, 22b to combine or the original digital data streams 22a, 22c to combine. In this embodiment, the two original digital data streams 22a and 22b are combined into the combined digital data stream 36a, and the original digital data streams 22c and 22d are combined into the combined digital data stream 36b.

Moreover, the original digital data streams 22a, 22b, 22c, and 22d are decoded by the decoder 16 from the encoded digital signal 12 having four channels of the original data streams 22a, 22b, 22c, and 22d. On the other hand, the four speakers 20a, 20b, 20c, 20d output the corresponding analog audio sound waves 14a, 14b, 14c, 14d from the analog signals 28a, 28b, 28c, 28d that are converted by the DAC 18.

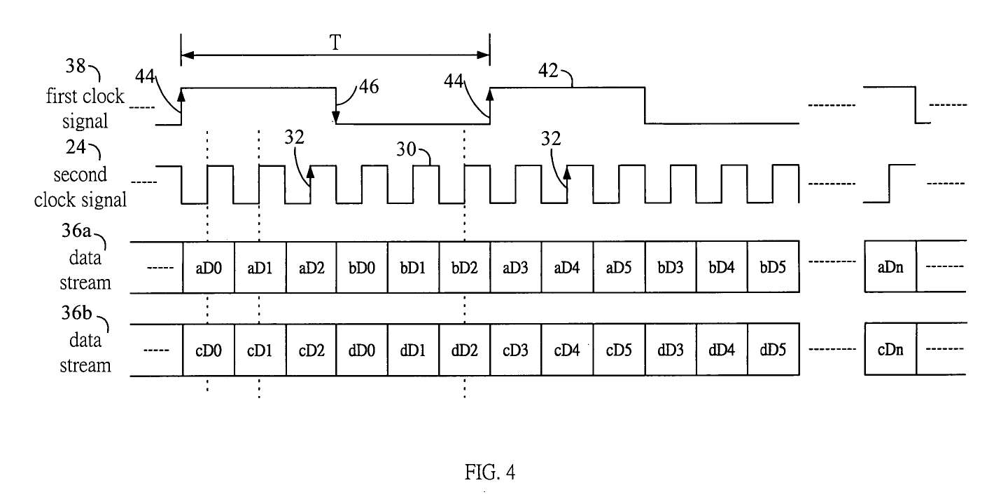

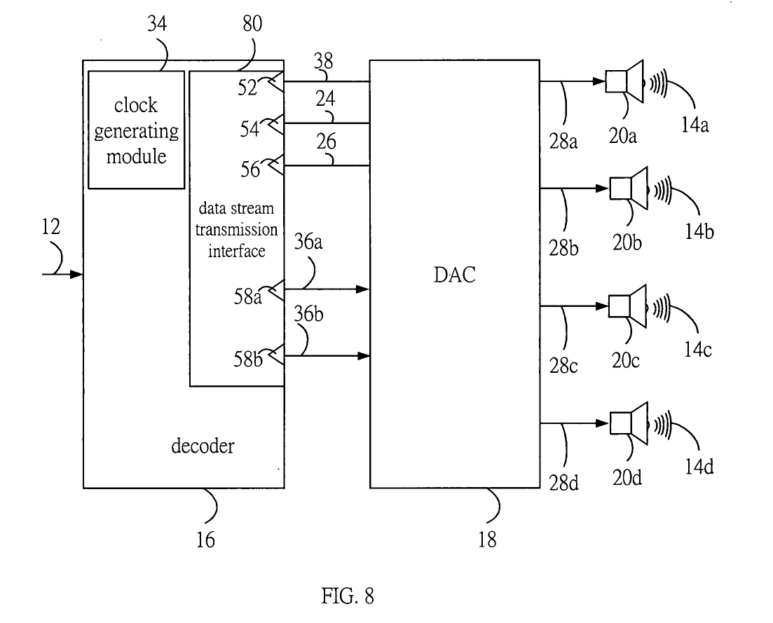

Please refer to FIG. 3 and FIG. 4. FIG. 4 is a signal diagram of the data streams 36a and 36b, the first clock signal 38, and the second clock signal 24 in FIG. 3. In the clock diagram, the horizontal axis denotes time line, and the vertical axis denotes the amplitude of the signal. The combined digital data stream 36a includes the digital data of the original digital data streams 22a and 22b. The combined digital data stream 36b includes the digital data of the original digital data streams 22c and 22d. In the present embodiment, two data streams are interleaved and arranged based on a predetermined converting period T to form each of the data streams 36a and 36b. The detailed description of the converting period T will be included in the following text when explaining FIG. 8.

The digital data in each of the original digital data streams 22a, 22b, 22c, 22d in the data streams of 36a, 36b may include one or, preferably, a plurality of digital data bits. In FIG. 4, these digital data are indicated as mDn; wherein m denotes one of the four said original digital data streams 22a, 22b, 22c, and 22d, and n denotes a sequential number. The sequential number comes from a series of natural numbers, increasing with time. For example, aD1 indicates the first digital data of the original digital data stream 22a, and cDn−1 indicates the (n−1)th digital data of the original data stream 22c.

The first clock signal 38 includes a plurality of square waves 42 with period T. Each square wave 42 has a positive edge 44 and a negative edge 46. Triggered by the positive edge 44, the plural digital data (for example: aD0, aD1, aD2) of the original data stream 22a in the DAC 18 are included in the combined data stream, for example 36a. Similarly, the plural digital data (for example: cD0, cD1, cD2) of the original data stream 22c in the DAC 18 are included in the combined data stream, for example 36b. Triggered by the negative edge 46, the plural digital data (for example: bD0, bD1, bD2) of the original data stream 22b in the DAC 18 are included in the combined data stream, for example 36a. Similarly, the plural digital data (for example: dD0, dD1, dD2) of the original data stream 22d in the DAC 18 are included in the combined data stream, for example 36b.

The second clock signal 24 includes a plurality of square waves 30. Each square wave 30 has a positive edge 32. When the positive edge 32 of the square wave 30 appears, the DAC 18 is triggered to convert the digital data in data streams 36a, 36b, which are formed by combining the original digital data streams 22a, 22c, and 22b, 22d respectively, into corresponding analog signals 28a, 28b, 28c, 28d.

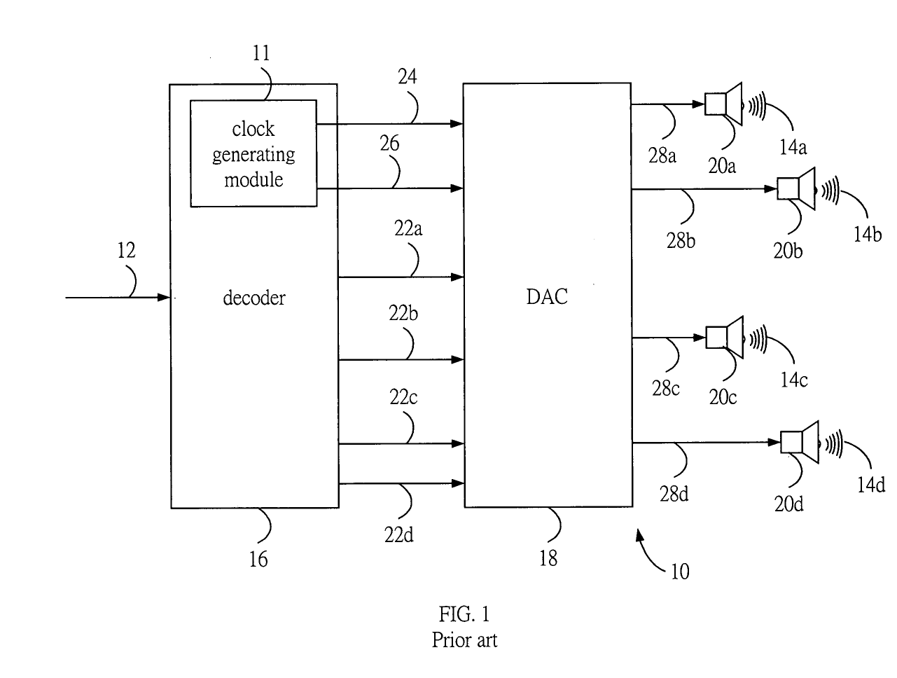

Comparing the conventional DSD data stream processing system 10 in FIG. 1 and the data stream processing system 40 according to the present invention, the number of signal lines that are connected to the DAC 18 is reduced from conventionally at least 6 lines (22a, 22b, 22c, 22d, 24, 26) to 5 lines (36a, 36b, 38, 24, 26). Therefore, the DSD data stream processing system according to the present invention can reduce the number of data streams transmitted to the DAC 18.

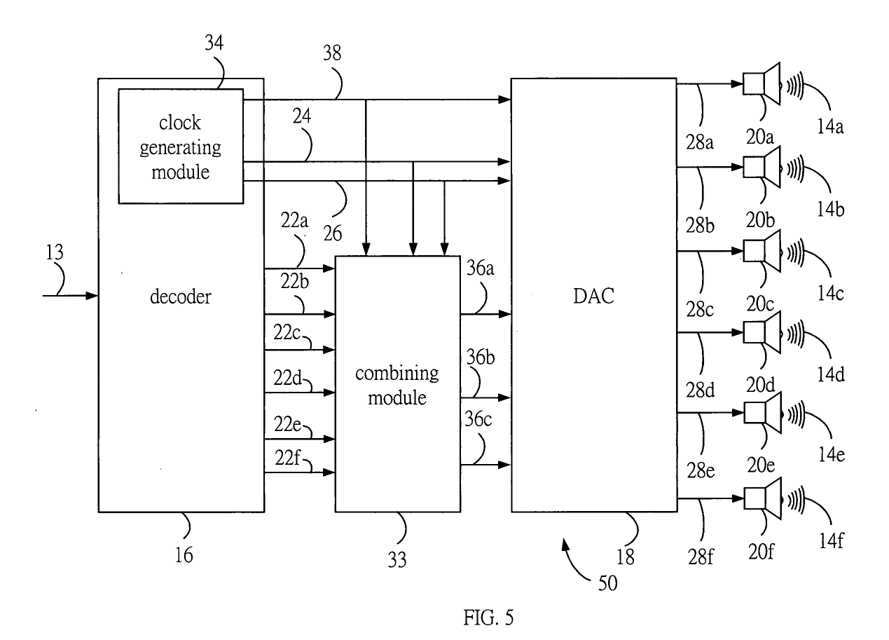

FIG. 5 illustrates a schematic diagram of a data stream processing system 50 in another embodiment according to the present invention. The data stream processing system 50 converts the encoded digital signal 13 with six channels of audio data into six original digital data streams 22a, 22b, 22c, 22d, 22e, and 22f by the decoder 16, then further converts the six original digital data streams into six corresponding analog signals 28a, 28b, 28c, 28d, 28e, and 28f.

The six original digital data streams 22a, 22b, 22c, 22d, 22e, 22f are combined by the combining module 33 to generate three combined digital data streams 36a, 36b, 36c. Therefore, totally six signal lines are required for connecting to the DAC 18. They are: the three combined digital data streams 36a, 36b, and 36c; the first clock signal 38 for defining a predetermined converting period in order to obtain the three combined digital data streams from the original digital data streams; and the second clock signal 24 for triggering a converting function to convert the digital data of each combined digital data stream into corresponding analog signals. The prior art needs at least eight signal lines for transmitting six original digital data streams, and the second clock signal 24, and the third clock signals 26. The embodiment of the present invention reduces that to six signal lines.

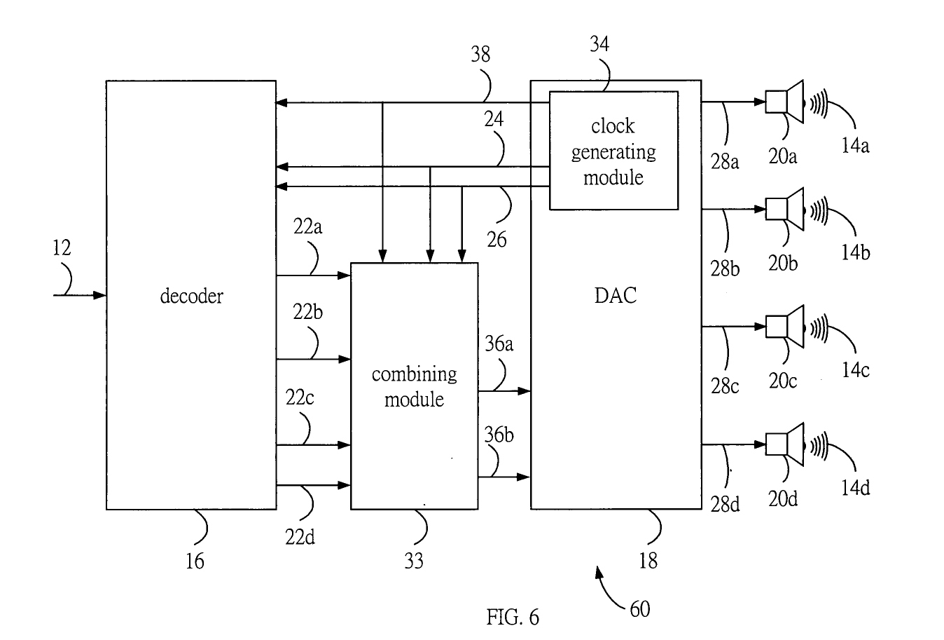

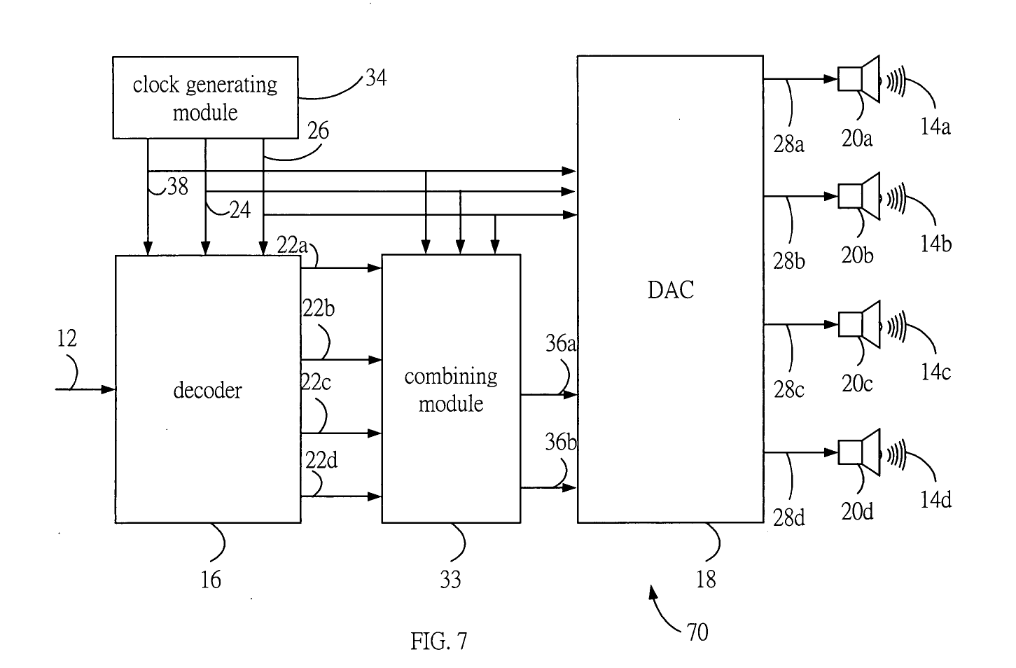

FIG. 6 and FIG. 7 are schematic diagrams of data stream processing systems 60 and 70 in another two embodiments, respectively, according to the present invention. The difference between the data stream processing systems 60 and 70 and the data stream processing system 40 in FIG. 3 is the different implementation of the clock generating module 34. The clock generating module 34 of the data stream processing system 60 is designed and integrated into the DAC 18, however, the clock-generating module 34 of the data stream processing system 70 is implemented and located independently away from the decoder 16 and the DAC 18.

FIG. 8 is a schematic diagram of a data stream transmission interface 80 according to the present invention. The data stream transmission interface 80 includes two data stream transmission pins 58a and 58b, a first clock signal transmission pin 52, a second clock signal transmission pin 54, and a third clock signal transmission pin 56. Please refer to FIG. 4 and FIG. 8. The data stream transmission pins 58a and 58b are for transmitting the combined digital data streams 36a and 36b decoded by the decoder 16 to the DAC 18. The data streams 36a and 36b respectively includes two different original digital data streams selected from the overall four original digital data streams 22a, 22b, 22c, 22d. For example, the combined digital data stream 36a includes the digital data of the original digital data streams 22a and 22c. The combined digital data stream 36b includes the digital data of the original digital data streams 22b and 22d. The plural bits in digital data of the original digital data streams 22a, 22b, 22c, 22d are interleaved and arranged by a predetermined interval to form digital data streams 36a, 36b. For example, in the embodiment shown in FIG. 4, every three digital data (for example: aD0, aD1, aD2) in the original digital data stream 22a are intervened by another three digital data (for example: bD0, bD1, bD2) in the original digital data stream 22b to form the combined digital data streams 36a. Similarly, every three digital data (for example: cD0, cD1, cD2) in the original digital data stream 22c are intervened by another three digital data (for example: dD0, dD1, dD2) in the original digital data stream 22d to form the combined digital data streams 36b.

The first clock signal transmission pin 52 is for transmitting the first clock signal 38. The first clock signal 38 defines the length of the converting period T, for example: six digital data as described above, so that the two original digital data streams in the combined data streams 36a and 36b can be identified for further separation. The second clock signal transmission pin 54 is for transmitting a second clock signal 24. The second clock signal 24 is used for triggering the DAC 18 to convert each digital data of the combined data streams 36a and 36b into corresponding analog signals 28a, 28b, 28c, 28d. Finally, the third clock signal transmission pin 56 is for transmitting the third clock signal 26.

The function of the decoder 16 is to decode the encoded digital signal 12, which includes a plurality of original digital data streams 22a, 22b, 22c, 22d, in order to generate the data stream 36a and 36b. Besides, the first clock signal 38 includes a plurality of square waves 42 with the converting period T. The length of the period T is a predetermined constant. In different embodiments, the predetermined converting period T could be changed according to its specific timing design. The converting period T can be every two digital data, or can be longer to include more digital data, for example: six digital data as described above.

With the explanations above, because the data stream transmission interface 80 includes the first clock signal transmission pin 52, the DAC can convert one combined digital data stream (for example: 36a) into two analog outputs (for example: 28a, 28b) according to the first clock signal 38. However, if the prior art needs two analog outputs, the pin design of the interface would require two original digital data stream inputs. Therefore, the feature of the present invention simplifies and reduces the pin design of the conventional interface to only one data stream input and one pin for the first clock signal input in the interface. Comparing the data stream transmission interface 80 of the present invention with the conventional DSD decoder and DAC transmission interface, more pins can thus be reduced if the number of the original digital data streams increases. For example, in the condition of four original digital data streams, the prior art needs four original digital data stream transmission pins and one second clock signal transmission pin, amounting to five pins totally. However, the present invention only needs two data stream transmission pins, a first clock signal transmission pin, and a second clock signal transmission pin, amounting to four pins totally. If there are six original digital data streams, the prior art needs six original digital data stream transmission pins, one second clock signal transmission pin, amounting to seven pins totally, whereas the present invention only needs three data stream transmission pins, one first clock signal transmission pin, and one second clock signal transmission pin, amounting to five pins totally.

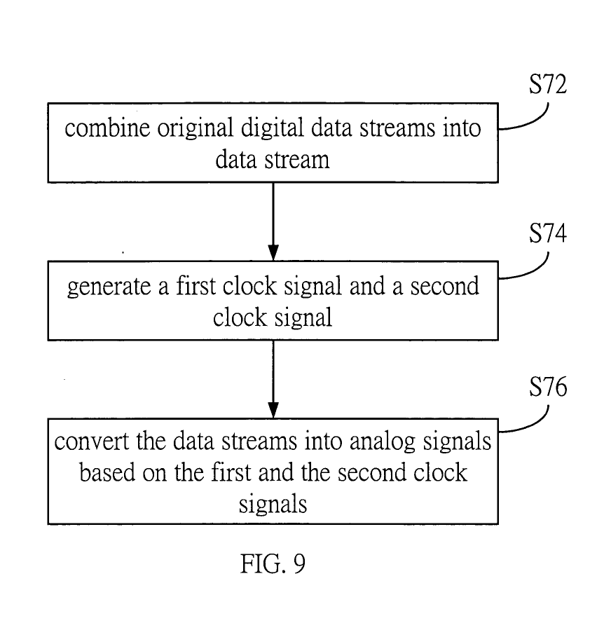

FIG. 9 is a flow chart of a data stream processing method according to one embodiment of the present invention. Take the 4-channel audio digital data signal 12 in FIG. 3 for example; the data stream processing method according to the present invention includes the following steps:

S72: Combine every two of the original digital data streams (ex. 22a, 22b, 22c, 22d) into one data stream based on a combining rule to generate two combined digital data streams 36a, 36b.

S74: Generate a first clock signal 38 and a second clock signal 24. The first clock signal 38 is used for defining a predetermined converting period T for the combined data streams 36a and 36b. The second clock signal 24 is used for triggering a D/A converting function for each digital data of the data streams 36a and 36b.

S76: Convert the digital data of each combined digital data streams 36a and 36b into corresponding analog signals 28a, 28b, 28c, 28d based on the first and the second clock signals 38 and 24.

According to the combining module 33 and the first clock signal 38 of the Direct Stream Digital (DSD) data stream processing system 40, 50, 60, and 70 in the embodiments, the number of the data streams transmitted to the DAC 18 can be reduced. Therefore, the signal lines and pins for IC chips can be decreased, and the cost and product size can be further reduced.

With the example and explanations above, the features and spirits of the invention are hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A data stream processing system of Direct Stream Digital (DSD) technology, for converting each original digital data streams processed by DSD into corresponding analog signals, the system comprising:
a combining module, for combining two original digital data streams into one data stream based on a combining rule, then generating a plurality of data streams;
a clock generating module, for generating a first clock signal and a second clock signal, the first clock signal being used for defining a predetermined converting period of each data stream, and the second clock signal is used for triggering a converting function of each digital data of each data stream; and
a digital-to-analog converter (DAC), for converting each digital data of each data streams into a corresponding analog signal based on the first and the second clock signals, then generating a plurality of analog signals.

2. The data stream processing system of claim 1, wherein the combining rule is to chose two original digital data streams from a plurality of original digital data streams.

3. The data stream processing system of claim 1, wherein the first clock signal has a positive edge and a negative edge in each predetermined converting period.

4. The data stream processing system of claim 3, wherein the positive edge triggers the DAC converting the digital data of a first original digital data stream of each data streams.

5. The data stream processing system of claim 4, wherein the negative edge triggers the DAC converting the digital data of a second original digital data stream of each data streams.

6. A data stream transmission interface of DSD technology, for transmitting data between a decoder and a DAC, the data stream transmission interface comprising:
at least one data stream transmission pin, for transmitting at least one data stream from the decoder to the DAC, the data stream comprising two different original digital data streams arranged by a predetermined interval;
a first clock signal transmission pin, for transmitting a first clock signal, the first clock signal defining a predetermined converting period for the data stream according to the predetermined interval;
a second clock signal transmission pin, for transmitting a second clock signal, the second clock signal being used for triggering the DAC converting each digital data of the data stream to a corresponding analog signal.

7. The data stream transmission interface of claim 6, wherein the decoder decodes a coding digital signal comprising a plurality of original digital data streams to generate the data stream.

8. The data stream transmission interface of claim 6, wherein the first clock signal has a positive edge and a negative edge in each predetermined converting period.

9. The data stream transmission interface of claim 8, wherein the positive edge triggers the DAC converting the digital data of a first original digital data stream.

10. The data stream transmission interface of claim 8, wherein the negative edge triggers the DAC converting the digital data of a second original digital data stream.

11. A data stream processing method of Direct Stream Digital (DSD) technology for converting each original digital data streams processed by DSD into corresponding analog signals, the method comprising:
combining two original digital data streams into one data stream based on a combining rule, then generating a plurality of data streams;
generating a first clock signal and a second clock signal, the first clock signal being used for defining a predetermined converting period of each data streams, and the second clock signal being used for triggering a converting process for each digital data of each data streams; and
converting each digital data of each data streams into a corresponding analog signal based on the first and the second clock signals, then generating a plurality of analog signals.

12. The data stream processing method of claim 11, wherein the combining rule is to chose two original digital data streams from a plurality of original digital data streams.

13. The data stream processing method of claim 11, wherein the first clock signal has a positive edge and a negative edge in each predetermined converting period.

14. The data stream processing method of claim 13, wherein the positive edge triggers converting the digital data of a corresponding first original digital data stream of each data streams.

15. The data stream processing method of claim 14, wherein the negative edge triggers converting the digital data of a corresponding second original digital data stream of each data streams.
